(19) United States
(12) Patent Application Publication
(10) Pub. No.: US 2007/0047201 A1
(43) Pub. Date: Mar. 1, 2007

(54) Fan with an arranging device for cable thereof

(76) Inventor: Shou-Te Yu, Taipei (TW)

Correspondence Address: G. LINK Co., LTD, 3550 Bell Road, MINOOKA, IL, 60447, US

(21) Appl. No.: 11/213,695

(22) Filed: Aug. 30, 2005

(51) Int. Cl. H05K 7/20

(52) U.S. Cl. 361/695

(57) ABSTRACT

A fan with an arranging device for cable thereof includes a frame member, a fan blade part and a cable. The frame member provides a driving part and a middle section and the middle section has a groove. The fan blade part is composed of a fan hub and fan blades surrounding the fan hub. The fan hub is rotationally joined to the driving part. The cable is attached to the driving part with an end thereof providing a connector. The cable can be received in the groove and located at the groove fast.

### BACKGROUND OF THE INVENTION

1. Field of the Invention

The present invention is related to a fan with an arranging device for cable thereof and particularly to a fan device, which is available for locating the cable.

2. Brief Description of the Related Art

Referring to FIGS. 1 and 2, the conventional fan includes a frame member 111 and a fan blade part 112. The fan blade part 112 is composed of a fan hub 112a and fan blades 112b surrounding the fan hub 112a. The frame member 111 has a driving part 111c being connected to the side opening 111b and a lateral side of the frame member 111 has a locating recess 111f e for receiving the connector 111e.

Referring to FIG. 3 in company with FIGS. 1 and 2, in case of the conventional fan being set up, the fan blade part 112 is rotationally joined to the driving part 111c and the connector 111e of the cable 111d is received in the recess 111f before a cover plate 111a encloses the side opening 111b.

Referring to FIG. 1 again, the cable 111d is coiled to the middle section 111g of the frame member 111 but the middle section 11g has a circular smooth surface such that the cable becomes jutting out of the frame 111 after being coiled to the middle section 111g. But, it often results in interference or interruption to the cover plate 111a during the cover plate 111a closing the side opening 111b. When the conventional fan is mounted to a hot component, a specific position or direction has to be arranged at the time of setting up the fan for the connector 111e being able to be connected. Because of the limitation, the conventional fan provides limited applications. In order to meet specific need of fan, the frame member 111 has to be fabricated with a new mold of frame. In this way, it increases production cost of the fan 11 with low compatibility in addition to being inconvenient assembled.

Further, in order to make the side opening 111b for locating the connector 111e, higher cost for the mold of frame is required and more manufacturing processes have to be added for working the side opening 111b. It is tedious and affects production efficiency.

Besides, the detachable cover plate 111a needs more work to make and it provides less compactness so that noise often occurs during the fan running.

### SUMMARY OF THE INVENTION

In order to solve the preceding problems, an object of the present invention is to provide a fan with an arranging device for cable thereof available for the cable being better located.

Another object of the present invention is to provide a fan with an arranging device for cable thereof, which is available for the cable being located conveniently.

A further object of the present invention is to provide a fan with an arranging device for cable thereof, which is capable of reducing work cost.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective sectional view of the conventional fan with an arranging device for cable thereof;

FIG. 2 is a disassembled perspective view of the conventional fan with an arranging device for cable thereof;

FIG. 3 is a perspective view of the conventional fan with an arranging device for cable thereof;

FIG. 4 is a perspective view of the first embodiment of a fan with an arranging device for cable thereof according to the present invention illustrating the cable before being received in the groove;

FIG. 5 is a perspective view of the first embodiment of a fan with an arranging device for cable thereof according to the present invention illustrating the cable after being received in the groove;

FIG. 6 is a perspective view of the second embodiment of a fan with an arranging device for cable thereof according to the present invention illustrating the cable before being received in the groove; and

FIG. 7 is a perspective view of the second embodiment of a fan with an arranging device for cable thereof according to the present invention illustrating the cable after being received in the groove.

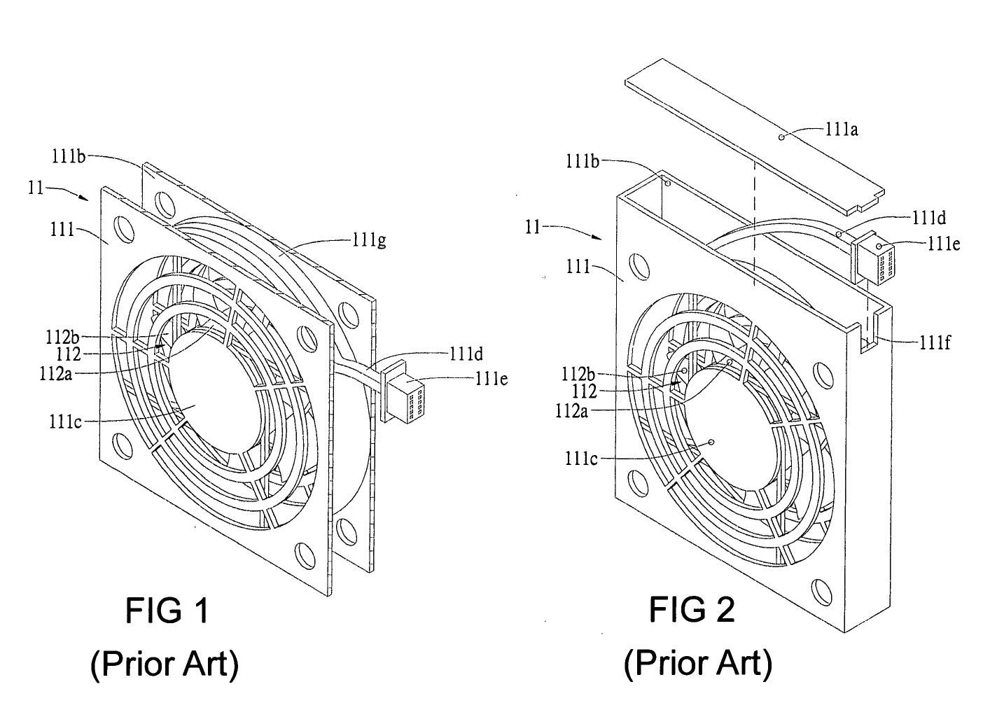

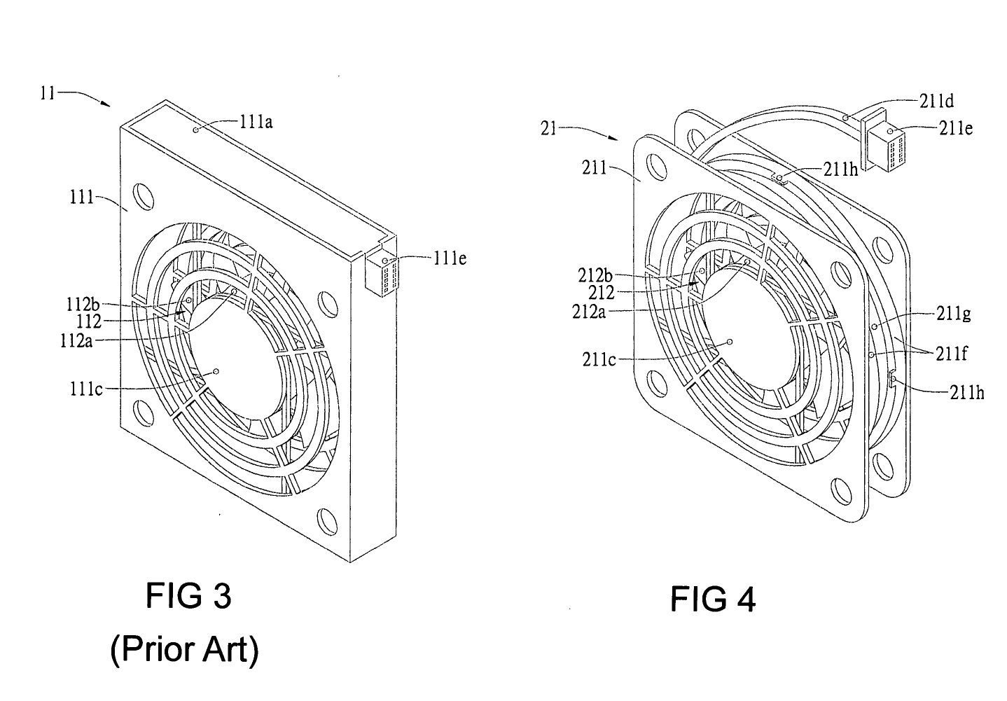

### DETAILED DESCRIPTION OF THE INVENTION

Referring to FIG. 4, the first preferred embodiment of a fan 21 with an arranging device for cable thereof according to the present invention includes a frame member 211 and a fan blade part 212. The fan blade part 212 is composed of a fan hub 212a and a plurality of fan blades 212b disposed to surrounding the fan hub 212a. The frame member 211 provides a driving part 211c for being joined to the fan hub 212a and a cable 211d is attached to the driving part 211c with a connector 211e being disposed at the end of the cable 211d.

The frame member 211 has a middle section 211f with a groove 211g for receiving the cable 211d and a stop part 211h is provided at the groove 211g.

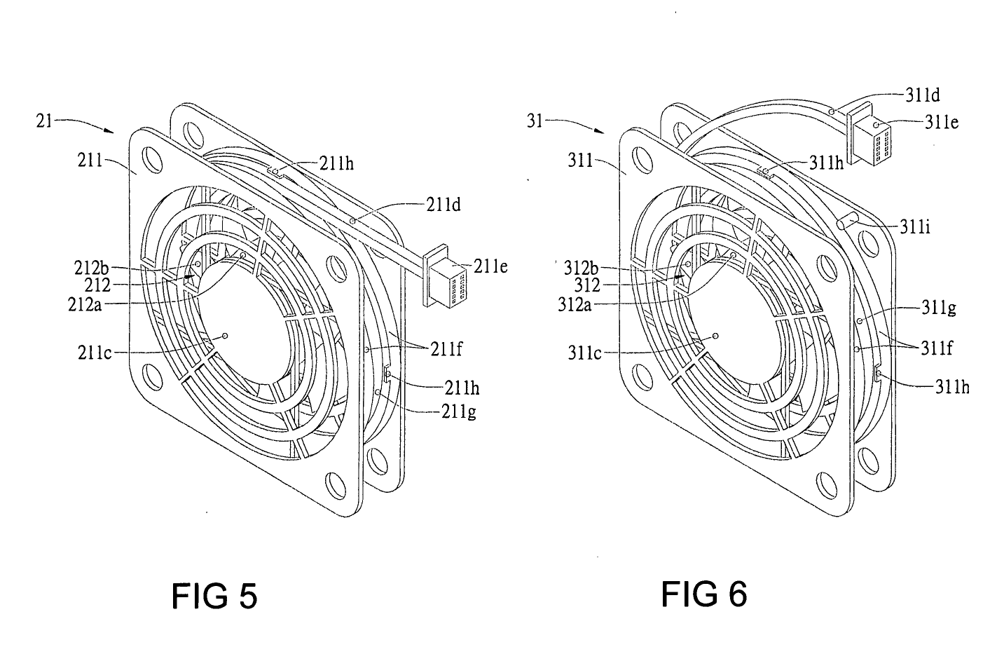

Referring to FIGS. 4 and 5, the cable 211d can be received in the groove 211g and the connector 211e can be connected at any directions and any positions as long as the cable 211d is in a state of being located. Hence, the cable 212d being arranged at the frame 211 via the groove 211g and the stop part 211h allows not only the cable 211d being located and received fast but also the connector 211e being connected conveniently.

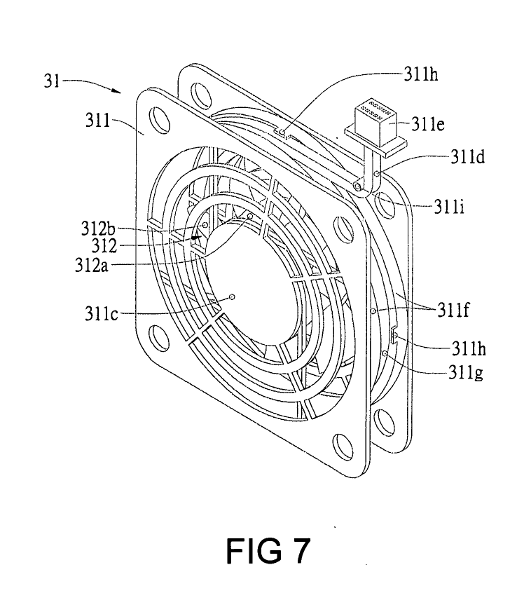

Referring to FIGS. 6 and 7, the second preferred embodiment of a fan with an arranging device for cable thereof according to the present invention is illustrated. The integral structure of the second embodiment is almost the same as the first embodiment. The difference of the present embodiment is in that the frame member 311 has a guide part 311i.

The cable 311d can be received in the groove 311g and the connector 311e can be connected at any directions and any positions as long as the cable 311d is in a state of being located. Hence, the cable 212d being arranged at the frame 211 via the groove 211g, the stop part 211h and the guide part 311i allows not only the cable 311d being located and received fast but also the connector 311e being connected conveniently.

Further, the groove (211g, 311g) can be provided with cone shape or circular shape and the stop part (211h, 311h) can be provided with a cylindrical shape or a slant shape. The guide part 311i can be inverted L shape or inverted U shape.

While the invention has been described with referencing to preferred embodiments thereof, it is to be understood that modifications or variations may be easily made without departing from the spirit of this invention, which is defined by the appended claims.

What is claimed is:

1. A fan with an arranging device for cable thereof, comprising:
a frame member, providing a driving part and a middle section;
a fan blade part, being composed of a fan hub and a plurality of fan blades surrounding the fan hub and the fan hub being rotationally joined to the driving part; and
a cable, being attached to the driving part with an end thereof providing a connector;
characterized in that the middle section has a groove for receiving the cable and the frame member has a guide part such that the cable is able to be located at the groove.

2. The fan with an arranging device for cable thereof as defined in claim 1, wherein the groove has a stop part.

3. A fan with an arranging device for cable thereof, comprising:
a frame member, providing a driving part and a middle section;
a fan blade part, being composed of a fan hub and a plurality of fan blades surrounding the fan hub and the fan hub being rotationally joined to the driving part; and
a cable, being attached to the driving part with an end thereof providing a connector;
characterized in that the middle section has a groove for receiving the cable such that the cable is able to be located at the groove.

4. The fan with an arranging device for cable thereof as defined in claim 3, wherein the groove has a stop part.
